(19) United States
(12) Patent Application Publication
(10) Pub. No.: US 2023/0329064 A1
(43) Pub. Date: Oct. 12, 2023

(54) DISPLAY DEVICE

(71) Applicant: Samsung Display Co., Ltd., Yongin-si (KR)

(72) Inventors: YUJIN KIM, Hwaseong-si (KR); KISOO PARK, Hwaseong-si (KR); SEUNG JUN YU, Cheonan-si (KR); HONGMIN YOON, Seoul (KR)

(73) Assignee: Samsung Display Co., Ltd., Yongin-si (KR)

(21) Appl. No.: 18/101,809

(22) Filed: Jan. 26, 2023

(30) Foreign Application Priority Data
Mar. 21, 2022 (KR) 10-2022-0034511

(51) Int. Cl. H10K 59/122; H10K 59/38; H10K 59/80

(52) U.S. Cl. CPC H10K 59/38; H10K 59/122; H10K 59/877; H10K 59/8792

(57) ABSTRACT

A display device according to an embodiment includes a circuit layer, a light-emitting element layer, an inorganic encapsulation film, a sub light control layer, a light control layer, a capping layer, and a color filter layer which are sequentially stacked each other. The sub light control layer includes a first to third sub light control parts, and a light control layer includes a bank and a first to third light control parts spaced apart from each other with the bank therebetween. Each of the sub light control layer and the light control layer includes quantum dots. The display device according to an embodiment includes the sub light control layer adj acent to the light-emitting element layer to exhibit improved light efficiency and color gamut.

### CROSS-REFERENCE TO RELATED APPLICATION(S)

This application claims priority to and benefits of Korean Patent Application No. 10-2022-0034511 under 35 U.S.C. § 119, filed on Mar. 21, 2022, in the Korean Intellectual Property Office (KIPO), the contents of which are incorporated by reference in its entirety.

### BACKGROUND

### 1. Technical Field

The disclosure herein relates to a display device including a sub light control part containing quantum dots.

### 2. Description of the Related Art

Various display devices for providing image information in multimedia apparatuses such as televisions, mobile phones, tablet computers, navigation units, and game consoles have been developed. Particularly, a display device including a liquid crystal display element, an organic electroluminescence display element, and the like, employs quantum dots to improve display quality. Methods for increasing the light efficiency of display devices containing quantum dots are being studied.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

The disclosure provides a display device having improved light efficiency and color gamut without including a filling layer.

An embodiment of the disclosure provides a display device, which may include: a circuit layer; a light-emitting element layer disposed above the circuit layer; an inorganic encapsulation film disposed above the light-emitting element layer; a sub light control layer disposed above the inorganic encapsulation film and including a first sub light control part, a second sub light control part, and a third sub light control part, each spaced apart from each other in a direction perpendicular to a thickness direction; a light control layer disposed above the sub light control layer and including a bank, a first light control part, a second light control part, and a third light control part, the first to third light control parts spaced apart from each other in the direction; a capping layer disposed above the light control layer and covering the light control layer; and a color filter layer disposed above the capping layer and including a first filter, a second filter and a third filter. The bank may be disposed between the first light control part, the second light control part, and the third light control part. The light-emitting element layer may include a pixel defining film with a pixel opening defined therein, a first electrode exposed in the pixel opening, a second electrode disposed above the first electrode, and a light-emitting layer disposed between the first electrode and the second electrode. Each of the sub light control layer and the light control layer may include quantum dots.

In an embodiment, the pixel defining film may be disposed between the first sub light control part, the second sub light control part, and the third sub light control part.

In an embodiment, an upper surface of the bank may contact a lower surface of the capping layer in the thickness direction.

In an embodiment, the display device may further include a sub-inorganic film disposed directly between the sub light control layer and the light control layer.

In an embodiment, the pixel defining film may be optically transparent, and the bank may include at least one of a black pigment and a black dye.

In an embodiment, a minimum width of the pixel defining film in the direction may be greater than a maximum width of the bank in the direction in a cross-sectional view.

In an embodiment, a minimum width of each of the first to third sub light control parts in the direction may be smaller than a minimum width of each of the first to third light control parts in the direction in a cross-sectional view.

In an embodiment, the pixel defining film and the bank may be integrated to form a partition wall, and the first to third sub light control parts and the first to third light control parts may each be disposed in a partition wall opening defined in the partition wall.

In an embodiment, the display device may further include a sub-inorganic film disposed directly between the first to third sub light control parts and the first to third light control parts.

In an embodiment, a minimum width of each of the first to third sub light control parts in the direction may be substantially equal to a minimum width of each of the first to third light control parts in the direction in a cross-sectional view.

In an embodiment, a first height of the partition wall may be greater than a second height of each of the first to third sub light control parts in a cross-sectional view, and each of the first height and the second height may be defined as a maximum height in the thickness direction from a surface of the circuit layer.

In an embodiment, the partition wall may be optically transparent, and the color filter layer may further include a light blocking portion overlapping the partition wall in the thickness direction.

In an embodiment, the first light control part and the first sub light control part may be integrated to form a first light control unit, the second light control part and the second sub light control part may be integrated to form a second light control unit, the third light control part and the third sub light control part may be integrated to form a third light control unit, the first to third light control units may be spaced apart from each other, and the partition wall may be disposed between the first light control unit, the second light control unit, and the third light control unit.

In an embodiment, each of the sub light control layer and the light control layer may further include a scatterer.

In an embodiment of the disclosure, a display device may include a light-emitting region and a non-light-emitting region, a light-emitting element layer; an inorganic encapsulation film disposed above the light-emitting element layer; a sub light control layer disposed above the inorganic encapsulation film and including a first sub light control part, a second sub light control part, and a third sub light control part, each spaced apart from each other in a direction perpendicular to a thickness direction; a light control layer disposed above the sub light control layer and including a bank, a first light control part, a second light control part, and a third light control part, the first to third light control parts spaced apart from each other in the direction; a sub-inorganic film disposed between the sub light control layer and the light control layer; a capping layer disposed above the light control layer and covering the light control layer; and a color filter layer disposed above the capping layer and including a first filter, a second filter, and a third filter. The bank may be disposed between the first light control part, the second light control part, and the third light control part, each of the sub light control layer and the light control layer may include quantum dots, at least a portion of each of the first to third light control parts may overlap the non-light-emitting region in the thickness direction, and the first to third sub light control parts may not overlap the non-light-emitting region in the thickness direction.

In an embodiment, the sub-inorganic film may be disposed between the sub light control layer and the light control layer in the light-emitting region, and the sub-inorganic film may be disposed between the inorganic encapsulation film and the light control layer in the non-light-emitting region.

In an embodiment, the light-emitting element layer may include a pixel defining film with a pixel opening defined therein, a first electrode exposed in the pixel opening, a second electrode disposed above the first electrode, and a light-emitting layer disposed between the first electrode and the second electrode. A minimum width of the pixel defining film in the direction may be greater than a maximum width of the bank in the direction in a cross-sectional view.

In an embodiment of the disclosure, a display device may include: a light-emitting region and a non-light-emitting region, a light-emitting element layer; an inorganic encapsulation film disposed above the light-emitting element layer; a sub light control layer disposed above the inorganic encapsulation film and including a first sub light control part, a second sub light control part, and a third sub light control part, each spaced apart from each other in a direction perpendicular to a thickness direction; a light control layer disposed above the sub light control layer and including a first light control part, a second light control part, and a third light control part, each spaced apart from each other in the direction; a sub-inorganic film disposed between the sub light control layer and the light control layer; a capping layer disposed above the light control layer and covering the light control layer; a color filter layer disposed above the capping layer and including a first filter, a second filter, and a third filter, and a partition wall. The light-emitting element layer may include a first electrode, a second electrode disposed above the first electrode, and a light-emitting layer disposed between the first electrode and the second electrode. Each of the sub light control layer and the light control layer may include quantum dots. The partition wall may be disposed between the first sub light control part, the second sub light control part, and the third sub light control part. The partition wall may be disposed between the first light control part, the second light control part, and the third light control part.

In an embodiment, the sub-inorganic film may be disposed between the first to third sub light control parts and the first to third light control parts in the light-emitting region, and the sub-inorganic film may be disposed between the partition wall and the capping layer in the non-light-emitting region.

In an embodiment, the first to third sub light control parts and the first to third light control parts may not overlap the non-light-emitting region in the thickness direction.

It is to be understood that the embodiments above are described in a generic and explanatory sense only and not for the purpose of limitation, and the disclosure is not limited to the embodiments described above.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a perspective view illustrating a display device according to an embodiment;

FIG. 2 is a plan view illustrating a portion of a display device according to an embodiment;

FIG. 3 is a schematic cross-sectional view taken along line I-I′ of FIG. 2;

FIG. 4 is an enlarged schematic cross-sectional view illustrating region XX′ of FIG. 3;

FIG. 5 is a schematic cross-sectional view illustrating a display device according to an embodiment;

FIG. 6 is an enlarged schematic cross-sectional view illustrating region YY′ of FIG. 5;

FIG. 7 is a schematic cross-sectional view illustrating a display device according to an embodiment; and

FIG. 8 is a schematic cross-sectional view illustrating a display device according to an embodiment.

### DETAILED DESCRIPTION OF THE EMBODIMENTS

The disclosure may be implemented in various modifications and have various forms and specific embodiments are illustrated in the drawings and described in detail in the text. It is to be understood, however, that the disclosure is not intended to be limited to the particular forms disclosed, but on the contrary, is intended to cover all modifications, equivalents, and alternatives falling within the spirit and scope of the disclosure.

When an element, such as a layer, is referred to as being “on”, “connected to”, or “coupled to” another element or layer, it may be directly on, connected to, or coupled to the other element or layer or intervening elements or layers may be present. When, however, an element or layer is referred to as being “directly on”, “directly connected to”, or “directly coupled to” another element or layer, there are no intervening elements or layers present. To this end, the term “connected” may refer to physical, electrical, and/or fluid connection, with or without intervening elements.

Also, when an element is referred to as being “in contact” or “contacted” or the like to another element, the element may be in “electrical contact” or in “physical contact” with another element; or in “indirect contact” or in “direct contact” with another element.

Like numbers or symbols refer to like elements throughout. Also, in the drawings, the thicknesses, ratios, and dimensions of the elements are exaggerated for effective description of the technical contents. As used herein, the term “and/or” includes any and all combinations of one or more of the associated listed items.

Although the terms first, second, etc. may be used to describe various elements, these elements should not be limited by these terms. These terms are only used to distinguish one element from another element. For example, a first element may be referred to as a second element, and similarly, a second element may also be referred to as a first element without departing from the scope of the disclosure. The singular forms include the plural forms as well, unless the context clearly indicates otherwise.

Spatially relative terms, such as “beneath”, “below”, “under”, “lower”, “above”, “upper”, “over”, “higher”, “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below”, for example, can encompass both an orientation of above and below. Furthermore, the apparatus may be otherwise oriented (e.g., rotated 90 degrees or at other orientations), and, as such, the spatially relative descriptors used herein interpreted accordingly.

The terms “above,” “top,” and “top surface” as used herein refer to an upward direction (i.e., a Z-axis direction) with respect to the display device. The terms “below,” “bottom,” and “bottom surface” as used herein refer to a downward direction (i.e., a direction opposite to the Z-axis direction) with respect to the display device. Further, the terms “left,” “right,” “upper,” and “lower” respectively indicate corresponding directions on the surface of the display device. For example, the term “left” indicates a direction opposite to an X-axis direction, the term “right” indicates the X-axis direction, the term “upper” indicates a Y-axis direction, and the term “lower” indicates a direction opposite to the Y-axis direction.

The terminology used herein is for the purpose of describing particular embodiments and is not intended to be limiting. As used herein, the singular forms, “a”, “an”, and “the” are intended to include the plural forms as well, unless the context clearly indicates otherwise. Moreover, the terms “comprises”, “comprising”, “includes”, and/or “including” when used in this specification, specify the presence of stated features, integers, steps, operations, elements, components, and/or groups thereof, but do not preclude the presence or addition of one or more other features, integers, steps, operations, elements, components, and/or groups thereof.

In the specification and the claims, the phrase “at least one of” is intended to include the meaning of “at least one selected from the group of” for the purpose of its meaning and interpretation. For example, “at least one of A and B” may be understood to mean “A, B, or A and B.”

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ± 30%, 20%, 10%, 5% of the stated value.

Unless otherwise defined, all terms (including technical and scientific terms) used herein have the same meaning as commonly understood by one of ordinary skill in the art to which the disclosure belongs. Also, terms, such as those defined in commonly used dictionaries, should be interpreted as having a meaning that is consistent with their meaning in the context of the relevant art and should not be interpreted in an idealized or overly formal sense unless expressly so defined herein.

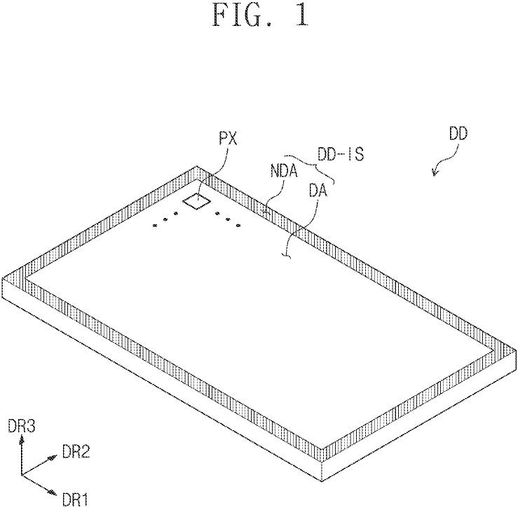

Hereinafter, a display device according to an embodiment of the disclosure will be described with reference to the drawings. FIG. 1 is a perspective view illustrating a display device according to an embodiment.

A display device DD of an embodiment may be activated in response to an electrical signal. For example, the display device DD may be a television, an external billboard, a portable electronic device, a tablet, a vehicle navigation unit, a game console, a personal computer, a notebook computer, or a wearable device, but the disclosure is not limited thereto.

The display device DD may display an image through a display surface DD-IS. The display surface DD-IS may be parallel to a plane defined by a first direction DR1 and a second direction DR2. The display surface DD-IS may include a display region DA and a non-display region NDA.

Pixels PX may be disposed in the display region DA, and the pixels PX may not be disposed in the non-display region NDA. The non-display region NDA may be defined along an edge of the display surface DD-IS. The non-display region NDA may surround the display region DA. However, the disclosure is not limited thereto, and the non-display region NDA may be disposed adjacent to only one side of the display region DA, or omitted.

FIG. 1 illustrates a display device DD having a flat display surface DD-IS, but the disclosure is not limited thereto. The display device DD may include a curved display surface or a stereoscopic display surface. The stereoscopic display surface may include multiple display regions indicating directions different from each other.

A thickness direction of the display device DD may be parallel to a third direction DR3 that is a normal direction of the plane defined by the first direction DR1 and the second direction DR2. The directions indicated by the first to third direction DR1, DR2, and DR3 illustrated in this specification may have a relative concept and may thus be changed to other directions. The directions indicated by the first to third directional DR1, DR2, and DR3 may be referred to as first to third directions, and thus denoted as the same reference numerals or symbols.

In this specification, a top surface (or a front surface) and a bottom surface (or a rear surface) of each member constituting the display device DD may be defined based on the third direction DR3. For example, among two surfaces facing the third direction DR3 in one member, a surface relatively adjacent to the display surface DD-IS may be defined as a front surface (or a top surface), and a surface relatively spaced apart from the display surface DD-IS may be defined as a rear surface (or a bottom surface). Also, in this specification, “above” and “below” may be defined based on the third direction DR3, the “above” may be defined based on a direction closer to the display surface DD-IS, and the “below” may be defined based on a direction away from the display surface DD-IS.

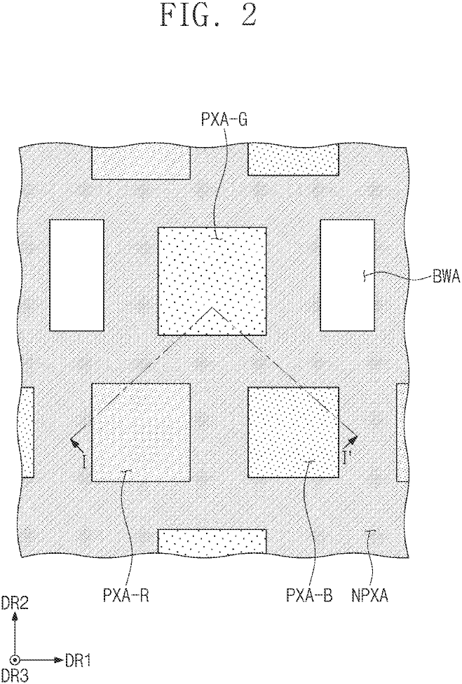

FIG. 2 is an enlarged plan view of a portion of a display device DD according to an embodiment. FIG. 2 illustrates a plane including three light-emitting regions PXA-R, PXA-B, and PXA-G and two bank well regions BWA adjacent thereto. The three light-emitting regions PXA-R, PXA-B, and PXA-G illustrated in FIG. 2 may be regions corresponding to the pixels PX (FIG. 1) and may be repeatedly disposed throughout the display region DA (FIG. 1). The light-emitting regions may include a first light-emitting region PXA-R, a second light-emitting region PXA-G, and a third light-emitting region PXA-B.

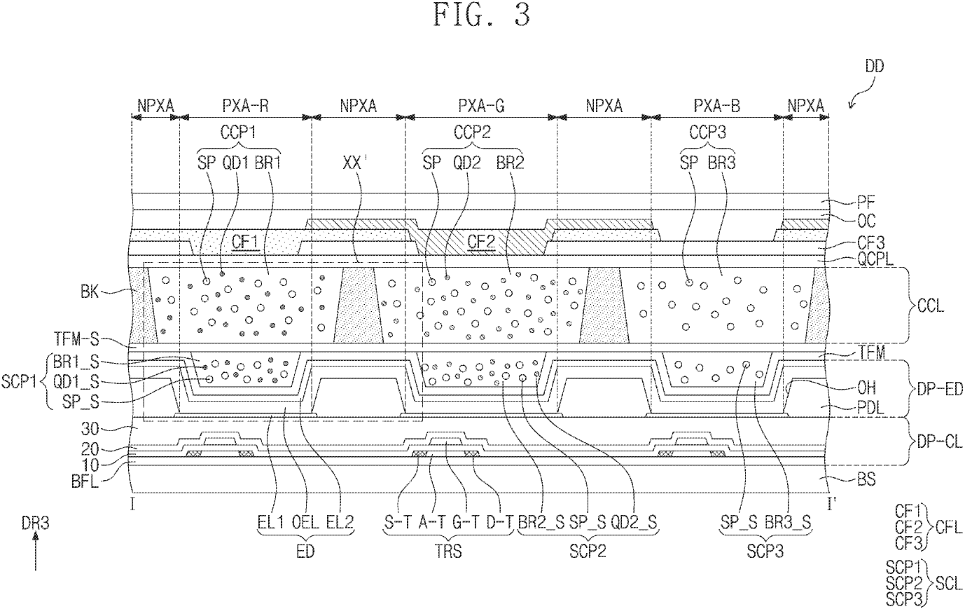

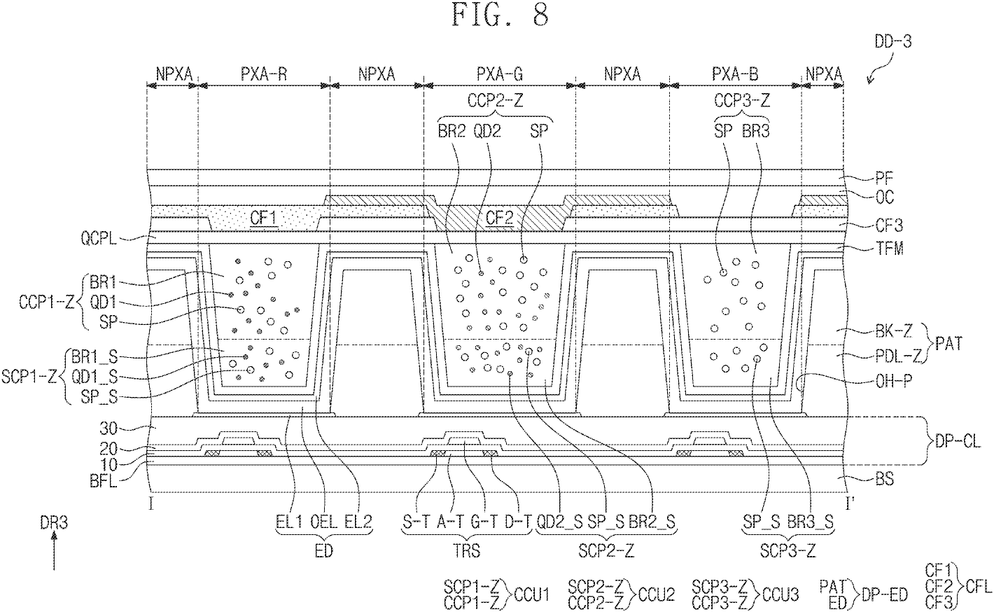

A non-light-emitting region NPXA may be disposed adjacent to the first to third light-emitting regions PXA-R, PXA-B, and PXA-G. The non-light-emitting region NPXA may set boundaries between the first to third light-emitting regions PXA-R, PXA-B, and PXA-G. The non-light-emitting region NPXA may surround the first to third light-emitting regions PXA-R, PXA-B, and PXA-G. In the non-light-emitting region NPXA, a structure that prevents color mixing between the first to third light-emitting regions PXA-R, PXA-B, and PXA-G, for example, a pixel defining film PDL (see FIG. 3), a bank (or first bank) BK (see FIG. 3), or a partition wall (or a second bank) PAT (see FIG. 8) may be disposed.

In FIG. 2, the first to third light-emitting regions PXA-R, PXA-B, and PXA-G have a same shape in a plan view and have different areas in a plan view, but the disclosure is not limited thereto. Areas of at least two of the first to third light-emitting regions PXA-R, PXA-B, and PXA-G may be equal to each other. Areas of the first to third pixel regions PXA-R, PXA-B, and PXA-G may be set according to the color of emitted light. The area of the light-emitting region emitting red light among primary colors may be the largest, and the area of the light-emitting region emitting blue light may be the smallest.

In FIG. 2, each of the first to third light-emitting regions PXA-R, PXA-B, and PXA-G is illustrated as having a rectangular shape in a plan view. In another embodiment, each of the first to third light-emitting regions PXA-R, PXA-B, and PXA-G may have a different shape, which includes a polygonal shape such as a rhombus or a pentagon. The first to third light-emitting regions PXA-R, PXA-B, and PXA-G may have a rectangular shape having rounded corners.

FIG. 2 illustrates that the second light-emitting region PXA-G is disposed in a first row, and the first light-emitting region PXA-R and the third light-emitting region PXA-B are disposed in a second row. However, the disclosure is not limited thereto, and the arrangement of the first to third light-emitting regions PXA-R, PXA-B, and PXA-G may be variously changed. For example, the first to third light-emitting regions PXA-R, PXA-B, and PXA-G may be arranged in a same row.

One of the first to third light-emitting regions PXA-R, PXA-B, and PXA-G may emit first color light, another one may emit second color light different from the first color light, and the other one may emit third color light different from the first color light and the second color light. For example, the first light-emitting region PXA-R may emit red light, the second light-emitting region PXA-G may emit green light, and the third light-emitting region PXA-B may emit blue light.

The bank well region BWA may be defined in the display region DA (see FIG. 1). The bank well region BWA may be a region for preventing defects due to erroneous deposition in the process of patterning multiple light control parts CCP1, CCP2, and CCP3 included in the light control layer CCL (see FIG. 3) to be described later. The bank well region BWA may be formed by removing a portion of the bank BK (FIG. 3). FIG. 2 illustrates that two bank well regions BWA are defined to be adj acent to the second light-emitting region PXA-G, but the disclosure is not limited thereto, and the shape and arrangement of the bank well regions BWA may be variously changed.

FIG. 3 is a schematic cross-sectional view taken along line I-I′ of FIG. 2. Referring to FIG. 3, the display device DD may include a base substrate BS, a circuit layer DP-CL disposed above the base substrate BS, a light-emitting element layer DP-ED disposed above the circuit layer DP-CL, an inorganic encapsulation film TFM disposed above the light-emitting element layer DP-ED, a sub light control layer SCL disposed above the inorganic encapsulation film TFM, a light control layer CCL disposed above the sub light control layer SCL, a capping layer QCPL disposed above the light control layer CCL, and a color filter layer CFL disposed above the capping layer QCPL. The display device DD may also include an overcoat layer OC disposed above the color filter layer CFL and a protection member PF disposed above the overcoat layer OC.

The base substrate BS may be a member for providing a base surface on which the circuit layer DP-CL is disposed. The base substrate BS may include a single layer or multiple layers. For example, the base substrate BS may have a three-layer structure of a polymer resin layer, an adhesive layer, and a polymer resin layer. For example, the polymer resin layer may include a polyimide-based resin. The polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

In this specification, the polyimide-based resin may mean a resin containing a functional group of polyimide. This may be similarly applied to the description of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin.

The circuit layer DP-CL may include a lower buffer layer BFL disposed above the base substrate BS, a first insulating layer 10 disposed above the lower buffer layer BFL, a second insulating layer 20 disposed above the first insulating layer 10, and a third insulating layer 30 disposed above the second insulating layer 20. For example, the lower buffer layer BFL, the first insulating layer 10, and the second insulating layer 20 may be an inorganic layer, and the third insulating layer 30 may be an organic layer.

The circuit layer DP-CL may include transistors TRS. The transistors TRS may each include an active A-T, a source S-T, a drain D-T, and a gate G-T. The active A-T, the source S-T, the drain D-T, and the gate G-T may be regions divided based on the doping concentration or conductivity of the semiconductor pattern. The active A-T, the source S-T, and the drain D-T may be disposed above the lower buffer layer BFL, and the gate G-T may be disposed above the first insulating layer 10. For example, the transistors TRS may be switching transistors or driving transistors for driving the light-emitting element ED of the light-emitting element layer DP-ED. However, this is only an example, and the transistors TRS are not limited thereto.

The light-emitting element layer DP-ED may include a pixel defining film PDL with a pixel opening OH defined therein, and a light-emitting element ED. The light-emitting element ED may include a first electrode EL1 exposed in the pixel opening OH, a second electrode EL2 facing the first electrode EL1, and a light-emitting layer OEL disposed between the first electrode EL1 and the second electrode EL2. Although not illustrated, the light-emitting element ED may also include a hole transport region disposed between the first electrode EL1 and the light-emitting layer OEL and an electron transport region disposed between the light-emitting layer OEL and the second electrode EL2. The hole transport region may include at least one of a hole injection layer, a hole transport layer, and an electron blocking layer. The electron transport region may include at least one of an electron injection layer, an electron transport layer, and a hole blocking layer.

The first electrode EL1 may be an anode or a cathode. The first electrode EL1 may be a pixel electrode. The first electrode EL1 may be a transmissive electrode, a transflective electrode, or a reflective electrode. The second electrode EL2 may be a common electrode. The second electrode EL2 may be a cathode or an anode, but the disclosure is not limited thereto. For example, in case that the first electrode EL1 is an anode, the second electrode EL2 may be a cathode; and in case that the first electrode EL1 is a cathode, the second electrode EL2 may be an anode. The second electrode EL2 may be a transmissive electrode, a transflective electrode, or a reflective electrode.

The light-emitting layer OEL may emit first color light. For example, the light-emitting layer OEL may generate blue light. The light-emitting layer OEL may generate light in a wavelength in range of about 410 nm to about 480 nm. Although FIG. 3 illustrates the light-emitting element ED including one light-emitting layer OEL, the light-emitting element ED may include multiple light-emitting layers. For example, the light-emitting element ED may be a light-emitting element having a tandem structure.

The light-emitting layer OEL may include a fluorescent or phosphorescent material. For example, the light-emitting layer OEL may include an anthracene derivative, a pyrene derivative, a fluoranthene derivative, a chrysene derivative, a dihydrobenzanthracene derivative, or a triphenylene derivative. The light-emitting layer OEL may include a metal organic complex as a light-emitting material.

FIG. 3 illustrates that the light-emitting layer OEL is provided as a common layer and overlaps (or extends over) the light-emitting regions PXA-R, PXA-G, and PXA-B and the non-light-emitting region NPXA, but the disclosure is not limited thereto. The light-emitting layer OEL may be patterned in the pixel opening OH and provided to overlap each of the light-emitting regions PXA-R, PXA-G, and PXA-B and not to overlap the non-light-emitting region NPXA.

The pixel opening OH of the pixel defining film PDL may expose at least a portion of the first electrode EL1. The pixel defining film PDL may overlap the non-light-emitting region NPXA and may not overlap the light-emitting regions PXA-R, PXA-G, and PXA-B. The pixel defining film PDL may include an organic material. For example, the pixel defining film PDL may be optically transparent. The pixel defining film PDL may have a transmittance of about 85% or more with respect to light having a wavelength of about 380 nm to about 780 nm.

In this specification, the term “overlapping” of two components is not limited to having the same area and the same shape in a plan view, and includes cases in which the two components have different areas and/or different shapes.

The inorganic encapsulation film TFM may protect the light-emitting element layer DP-ED from moisture and oxygen. The inorganic encapsulation film TFM may include an inorganic material. For example, the inorganic encapsulation film TFM may include at least one of silicon nitride, silicon oxynitride, silicon oxide, titanium oxide, aluminum oxide, and the like, but is not particularly limited thereto.

The sub light control layer SCL may include a first sub light control part SCP1 that converts a first color light provided from the light-emitting element ED into a second color light, a second sub light control part SCP2 that converts the first color light into a third color light, and a third sub light control part SCP3 that transmits the first color light. The first sub light control part SCP1 may provide red light which is the second color light, the second sub light control part SCP2 may provide green light which is the third color light, and the third sub light control part SCP3 may transmit and provide blue light which is the first color light provided from the light-emitting element ED.

The first sub light control part SCP1 may include a first base resin BR1_S, first quantum dots QD1_S dispersed in the first base resin BR1_S, and scatterers SP_S dispersed in the first base resin BR1_S. The second sub light control part SCP2 may include a second base resin BR2_S, second quantum dots QD2_S dispersed in the second base resin BR2_S, and scatterers SP_S dispersed in the second base resin BR2_S. The third sub light control part SCP3 may include a third base resin BR3_S and scatterers SP_S dispersed in the third base resin BR3_S.

The first to third base resins BR1_S, BR2_S, and BR3_S may be a medium in which the quantum dots QD1_S and QD2_S and the scatterer SP_S are dispersed, and may be composed of various resin compositions that may be generally referred to as a binder. For example, the first to third base resins BR1_S, BR2_S, and BR3_S may be an acrylic resin, a urethane-based resin, a silicone-based resin, or an epoxy-based resin. The first to third base resins BR1_S, BR2_S, and BR3_S may be transparent resins. The first base resin BR1_S, the second base resin BR2_S, and the third base resin BR3_S may be the same as or different from each other.

The scatterer SP_S may be an inorganic particle. For example, the scatterer SP_S may include at least one of TiO₂, ZnO, Al₂O₃, SiO₂, and hollow silica. The scatterer SP_S may include any one of TiO₂, ZnO, Al₂O₃, SiO₂, and hollow silica, or may include a mixture of two or more materials selected from the group consisting of TiO₂, ZnO, Al₂O₃, SiO₂, and hollow silica.

For example, the first quantum dot QD1_S may be a red quantum dot, and the second quantum dot QD2_S may be a green quantum dot. The core of each of the quantum dots QD1_S and QD2_S may be selected from the group consisting of a group II-VI compound, a group III-VI compound, a group I-III-VI compound, a group III-V compound, a group III-II-V compound, a group IV-VI compound, a group IV element, a group IV compound, and a combination thereof.

The group II-VI compound may be selected from the group consisting of: a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and a mixture thereof.

The group III-VI compound may include a binary compound such as In₂S₃ and In₂Se₃, a ternary compound such as InGaS₃ and InGaSe₃, or any combination thereof.

The group I-III-VI compound may include a ternary compound such as AgInS, AgInS₂, CuInS, CuInS₂, AgGaS₂, CuGaS₂ CuGaO₂, AgGaO₂, AgAlO₂, and a mixture thereof, or a quaternary compound such as AgInGaS₂ and CuInGaS₂.

The group III-V compound may be selected from the group consisting of: a binary compound selected from the group consisting of GaN, GaP, GaAs, GaSb, AlN, AlP, AlAs, AlSb, InN, InP, InAs, InSb, and a mixture thereof; a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and a mixture thereof; and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. The group III-V compound may also include a group II metal. For example, InZnP or the like may be selected as the group III-II-V compound.

The group IV-VI compound may be selected from the group consisting of: a binary compound selected from the group consisting of SnS, SnSe, SnTe, PbS, PbSe, PbTe, and a mixture thereof; a ternary compound selected from the group consisting of SnSeS, SnSeTe, SnSTe, PbSeS, PbSeTe, PbSTe, SnPbS, SnPbSe, SnPbTe, and a mixture thereof; and a quaternary compound selected from the group consisting of SnPbSSe, SnPbSeTe, SnPbSTe, and a mixture thereof. The group IV element may be selected from the group consisting of Si, Ge, and a mixture thereof. The group IV compound may be a binary compound selected from the group consisting of SiC, SiGe, and a mixture thereof.

Here, the binary compound, the ternary compound, or the quaternary compound may be formed in the particle with a uniform concentration, or may be formed in the particle with partially different concentration distributions. The quantum dot may have a core/shell structure in which one quantum dot surrounds another quantum dot. The core/shell structure may have a concentration gradient in which the concentration of elements in the shell decreases toward the core.

In some embodiments, the quantum dots QD1_S and QD2_S may each have a core-shell structure including a core having the above-described nanocrystals and a shell surrounding the core. The shell of each of the quantum dots QD1_S and QD2_S may serve as a protective layer for maintaining semiconductor characteristics by preventing chemical modification of the core and/or serve as a charging layer for imparting electrophoretic characteristics to the quantum dot. The shell may be a single layer or multiple layers. The shells of the quantum dots QD1_S and QD2_S may include a metal or non-metal oxide, a semiconductor compound, or a combination thereof.

For example, the metal or non-metal oxide may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and NiO or a ternary compound such as MgAl₂O₄, CoFe₂O₄, NiFe₂O₄, and CoMn₂O₄, but the disclosure is not limited thereto.

The semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and the like, but the disclosure is not limited thereto.

The quantum dots QD1_S and QD2_S may have a full width of half maximum (FWHM) of an emission wavelength spectrum of about 45 nm or less, about 40 nm or less, or about 30 nm or less, and within this range, the color purity or the color reproducibility may be improved. Light emitted through such quantum dots QD1_S and QD2_S may be emitted in all directions, so that wide viewing angle characteristics may be improved.

The shapes of the quantum dots QD1_S and QD2_S are not particularly limited to shapes commonly used in the field. The quantum dots may have shapes such as a spherical shape, a pyramidal shape, a multi-arm shape, a cubic nanoparticle, a nanotube, a nanowire, a nanofiber, and a nanoplatelet particle. The quantum dots QD1_S and QD2_S may control the color of emitted light based on the particle size, and accordingly, the quantum dots may have various emission colors such as blue, red, and green.

The first sub light control part SCP1, the second sub light control part SCP2, and the third sub light control part SCP3 may be spaced apart from each other in a direction perpendicular to the thickness direction DR3. The first sub light control part SCP1, the second sub light control part SCP2, and the third sub light control part SCP3 may be spaced apart from each other with the pixel defining film PDL therebetween. The first sub light control part SCP1, the second sub light control part SCP2, and the third sub light control part SCP3 may be disposed in the pixel opening OH of the pixel defining film PDL.

The first sub light control part SCP1, the second sub light control part SCP2, and the third sub light control part SCP3 may not overlap the non-light-emitting region NPXA. The first sub light control part SCP1, the second sub light control part SCP2, and the third sub light control part SCP3 may overlap the light-emitting regions PXA-R, PXA-G, and PXA-B. The first sub light control part SCP1 may overlap the first light-emitting region PXA-R, the second sub light control part SCP2 may overlap the second light-emitting region PXA-R, and the third sub light control part SCP3 may overlap the third light-emitting region PXA-B.

In an embodiment, the first sub light control part SCP1, the second sub light control part SCP2, and the third sub light control part SCP3 may be disposed adjacent to the light-emitting layer OEL. The first sub light control part SCP1, the second sub light control part SCP2, and the third sub light control part SCP3 may be spaced apart from the light-emitting element layer DP-ED with the inorganic encapsulation film TFM therebetween. The sub light control layer SCL, which includes first sub light control part SCP1, the second sub light control part SCP2, and the third sub light control part SCP3, may be in contact with the inorganic encapsulation film TFM. The light-emitting element layer DP-ED may be in contact with the inorganic encapsulation film TFM. The sub light control layer SCL may be disposed adjacent to the light-emitting layer OEL generating light, and improve the light output efficiency of the display device DD.

In a typical display device, multiple members (e.g., an inorganic encapsulation layer, an organic encapsulation layer, a filling layer, etc.) are disposed between a quantum dot-containing member (e.g., a light control layer) and a light-emitting element layer. As light generated in the light-emitting layer including the light-emitting element layer is emitted through the members, the light efficiency of the display device is deteriorated.

The sub light control layer SCL according to an embodiment may replace an organic encapsulation film disposed between two inorganic encapsulation films in a typical display device. In the display device DD according to an embodiment, since the sub light control layer SCL containing the quantum dots QD1_S and QD2_S is disposed adjacent to the light-emitting layer OEL, members through which light generated from the light-emitting element layer DP-ED has to pass until the light reaches the sub light control layer SCL containing the quantum dots QD1_S and QD2_S may be reduced. For example, a path of light until the light generated in the light-emitting element layer DP-ED reaches the sub light control layer SCL may be shortened. Accordingly, in an embodiment, the display device DD including the sub light control layer SCL that is adjacent to the light-emitting layer OEL and contains the quantum dots QD1_S and QD2_S may exhibit improved light efficiency.

The light control layer CCL may include a bank BK, a first light control part CCP1, a second light control part CCP2, and a third light control part CCP3. The first light control part CCP1, the second light control part CCP2, and the third light control part CCP3 may be spaced apart from each other with the bank BK therebetween. The first light control part CCP1, the second light control part CCP2, and the third light control part CCP3 may be spaced apart from each other in a direction perpendicular to the thickness direction DR3.

The first light control part CCP1 may convert the first color light provided from the light-emitting element ED into fourth color light, and the second light control part CCP2 may convert the first color light into fifth color light. The third light control part CCP3 may transmit the first color light. For example, the first light control part CCP1 may provide red light which is the fourth color light, the second light control part CCP2 may provide green light which is the fifth color light, and the third light control part CCP3 may transmit and provide blue light which is the first color light provided from the light-emitting element ED. The first light control part CCP1 and the first sub light control part SCP1 may overlap. The second light control part CCP2 and the second sub light control part SCP2 may overlap. The third light control part CCP3 may overlap the third sub light control part SCP3.

The fourth color light provided by the first light control part CCP1 and the second color light provided by the first sub light control part SCP1 may have a same wavelength range. The fifth color light provided by the second light control part CCP2 and the third color light provided by the second sub light control part SCP2 may have a same wavelength range.

The first light control part CCP1 may include a fourth base resin BR1, fourth quantum dots QD1 dispersed in the fourth base resin BR1, and scatterers SP dispersed in the fourth base resin BR1. The second light control part CCP2 may include a fifth base resin BR2, fifth quantum dots QD2 dispersed in the fifth base resin BR2, and scatterers SP dispersed in the fifth base resin BR2. The third light control part CCP3 may include a sixth base resin BR3 and scatterers SP dispersed in the sixth base resin BR3.

The fourth to sixth base resins BR1, BR2, and BR3 may each be a medium in which the quantum dots QD1 and QD2 and the scatterer SP are dispersed, and may be composed of various resin compositions that may be generally referred to as a binder. For example, the fourth to sixth base resins BR1, BR2, and BR3 may be an acrylic resin, a urethane-based resin, a silicone-based resin, or an epoxy-based resin. The fourth to sixth base resins BR1, BR2, and BR3 may be transparent resins. The fourth base resin BR1, the fifth base resin BR2, and the sixth base resin BR3 may be the same as or different from each other.

The first base resin BR1_S of the first sub light control part SCP1 and the fourth base resin BR1 of the first light control part CCP1 may be the same as or different from each other. The second base resin BR2_S of the second sub light control part SCP2 and the fifth base resin BR2 of the second light control part CCP2 may be the same as or different from each other. The third base resin BR3_S of the third sub light control part SCP3 and the sixth base resin BR3 of the third light control part CCP3 may be the same as or different from each other.

The scatterers SP of the first to third light control parts CCP1, CCP2, and CCP3 may be inorganic particles. For example, the scatterers SP may include at least one of TiO₂, ZnO, Al₂O₃, SiO₂, and hollow silica. The scatterers SP may include any one of TiO₂, ZnO, Al₂O₃, SiO₂, and hollow silica, or may include a mixture of two or more materials selected from a group consisting of TiO₂, ZnO, Al₂O₃, SiO₂, and hollow silica. The scatterers SP of the first to third light control parts CCP1, CCP2, and CCP3 may be same as or different from the scatterers SP_S of the first to third sub light control parts SCP1, SCP2, and SCP3.

The fourth quantum dot QD1 of the first light control part CCP1 may be a red quantum dot, and the fifth quantum dot QD2 of the second light control part CCP2 may be a green quantum dot. For the fourth quantum dot QD1 and the fifth quantum dot QD2, the description of the quantum dot, which has been made above, may be similarly applied.

The fourth quantum dot QD1 of the first light control part CCP1 and the first quantum dot QD1_S of the first sub light control part SCP1 may convert the first color light into light having a same wavelength range. The fourth quantum dot QD1 of the first light control part CCP1 may be same as or different from the first quantum dot QD1_S of the first sub light control part SCP1.

The fifth quantum dot QD2 of the second light control part CCP2 and the second quantum dot QD2_S of the second sub light control part SCP2 may convert the first color light into light having a same wavelength range. The fifth quantum dot QD2 of the second light control part CCP2 may be same as or different from the second quantum dot QD2_S of the second sub light control part SCP2.

In an embodiment, at least a portion of each of the first light control part CCP1, the second light control part CCP2, and the third light control part CCP3 may overlap the non-light-emitting region NPXA. In a cross-sectional view parallel to the third direction DR3, a side and another side of the first light control part CCP1 may be disposed in the non-light-emitting region NPXA, a side and another side of the second light control part CCP2 may be disposed in the non-light-emitting region NPXA, and a side and another side of the third light control part CCP3 may be disposed in the non-light-emitting region NPXA. The side and the another side of each of the first to third light control parts CCP1, CCP2, and CCP3 may be spaced apart from each other in a direction perpendicular to the thickness direction DR3.

Referring to FIG. 3, in the non-light-emitting region NPXA between first light-emitting region PXA-R and second light-emitting region PXA-G, the another side of the first light control part CCP1 and the side of the second light control part CCP2 may be spaced apart from each other with the bank BK therebetween. In the non-light-emitting region NPXA between the second light-emitting region PXA-G and the third light-emitting region PXA-B, the another side of the first light control part CCP1 and the side of the second light control part CCP2 may be spaced apart from each other with the bank BK therebetween. Although not illustrated, in the non-light-emitting region NPXA between the third light-emitting region PXA-B and the first light-emitting region PXA-R of adj acent pixel, the another side of the third light control part CCP3 and the side of the first light control part CCP1 of the adjacent pixel may be spaced apart from each other with the bank BK therebetween.

The bank BK may be a black matrix. In an embodiment, the bank BK may include an organic light blocking material or an inorganic light blocking material which contains a black pigment or a black dye. The bank BK may overlap the non-light-emitting region NPXA and may not overlap the light-emitting regions PXA-R, PXA-G, and PXA-B.

The capping layer QCPL may cover the light control layer CCL. For example, the capping layer QCPL may cover the first to third light control parts CCP1, CCP2, and CCP3. The capping layer QCPL may be optically transparent.

The color filter layer CFL may include a first filter CF1, a second filter CF2, and a third filter CF3. The first filter CF1 may transmit the second color light, the second filter CF2 may transmit the third color light, and the third filter CF3 may transmit the first color light. For example, the first filter CF1 may be a red filter, the second filter CF2 may be a green filter, and the third filter CF3 may be a blue filter. Each of the first to third filters CF1, CF2, and CF3 may include a polymer photosensitive resin and a pigment or dye. The first filter CF1 may include a red pigment or dye, the second filter CF2 may include a green pigment or dye, and the third filter CF3 may include a blue pigment or dye. However, the disclosure is not limited thereto, and the third filter CF3 may not include a pigment or dye. The third filter CF3 may include a polymer photosensitive resin and may not include a pigment or dye. The third filter CF3 may be transparent. The third filter CF3 may be formed of a transparent photosensitive resin.

The first filter CF1 and the second filter CF2 may be yellow filters. The first filter CF1 and the second filter CF2 are not separated from each other and may be integral with each other.

Referring to FIG. 3, at least two filters of the first to third filters CF1, CF2 and CF3 may overlap in the non-light-emitting region NPXA. However, this is only an example, and the arrangement of the first to third filters CF1, CF2, and CF3 in the non-light-emitting region NPXA is not limited thereto.

The overcoat layer OC may be a planarization layer. The overcoat layer OC may be provided with a non-uniform thickness. An upper surface of the overcoat layer OC may be a flat surface and may be a surface spaced apart from the capping layer QCPL and adjacent to the protection member PF.

The protection member PF may be disposed to protect components disposed thereunder. For example, the protection member PF may include a window. The protection member PF may include a functional layer such as an anti-fingerprint coating layer, an antireflection coating layer, and/or a hard coating layer. However, this is only an example, and the configuration of the protection member PF is not limited to any one embodiment.

The display device DD according to an embodiment may also include a sub-inorganic film TFM-S disposed directly between the sub light control layer SCL and the light control layer CCL. The sub-inorganic film TFM-S may include an inorganic material. For example, the sub-inorganic film TFM-S may include silicon nitride, silicon oxynitride, silicon oxide, titanium oxide, aluminum oxide, or the like, but is not particularly limited thereto.

The first to third sub light control parts SCP1, SCP2, and SCP3 may be disposed between the inorganic encapsulation film TFM and the sub-inorganic film TFM-S. The sub-inorganic film TFM-S may be disposed between the sub light control layer SCL and the light control layer CCL in the light-emitting regions PXA-R, PXA-G, and PXA-B, and may be disposed between the inorganic encapsulation film TFM and the light control layer CCL in the non-light-emitting region NPXA. For example, in the light-emitting regions PXA-R, PXA-G, and PXA-B, the sub-inorganic film TFM-S may contact the first to third sub light control parts SCP1, SCP2, and SCP3 and the first to third light control parts CCP1, CCP2, and CCP3. In the non-light-emitting region NPXA, the sub-inorganic film TFM-S may contact the inorganic encapsulation film TFM and the bank BK. In the non-light-emitting region NPXA, the sub-inorganic film TFM-S may contact an edge and another edge of each of the first to third light control parts CCP1, CCP2, and CCP3 spaced apart from each other with the bank BK therebetween.

In the non-light-emitting region NPXA, the bank BK may overlap the pixel defining film PDL. In the non-light-emitting region NPXA, the area of the bank BK may be smaller than the area of the pixel defining film PDL in a plan view. Accordingly, at least a portion of the first to third light control parts CCP1, CCP2, and CCP3 spaced apart from each other with the bank BK therebetween may overlap the non-light-emitting region NPXA. The first to third sub light control parts SCP1, SCP2, and SCP3 spaced apart from each other with the pixel defining film PDL therebetween may not overlap the non-light-emitting region NPXA.

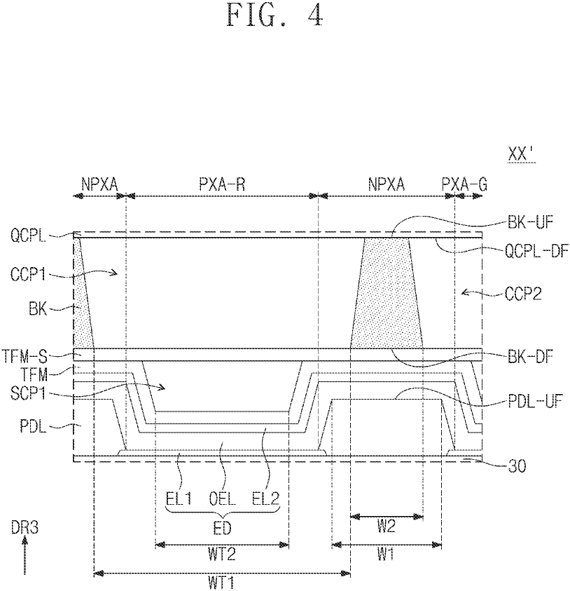

FIG. 4 is an enlarged schematic cross-sectional view illustrating region XX′ of FIG. 3. Referring to FIG. 4, the bank BK may include an upper surface BK-UF and a lower surface BK-DF spaced apart in parallel in the thickness direction DR3. The upper surface BK-UF of the bank BK may contact the capping layer QCPL. For example, the upper surface BK-UF of the bank BK may contact a lower surface QCPL-DF of the capping layer QCPL. The lower surface BK-DF of the bank BK may contact the sub-inorganic film TFM-S. The bank BK may be disposed between the sub-inorganic film TFM-S and the capping layer QCPL.

In a cross-sectional view parallel to the third direction DR3, the bank BK may have a maximum width W2 on a surface (for example, the lower surface BK-DF) of the bank BK adjacent to the inorganic encapsulation film TFM. The maximum width W2 of the bank BK may be measured parallel to a direction perpendicular to the thickness direction DR3.

In a cross-sectional view parallel to the third direction DR3, the pixel defining film PDL may have a minimum width W1 on a surface PDL-UF of the pixel defining film PDL adjacent to the inorganic encapsulation film TFM. The minimum width W1 of the pixel defining film PDL may be measured parallel to a direction perpendicular to the thickness direction DR3. The light-emitting layer OEL may be disposed on the surface PDL-UF of the pixel defining film PDL.

In a cross-sectional view parallel to the third direction DR3, the minimum width W1 of the pixel defining film PDL may be greater than the maximum width W2 of the bank BK. The minimum width W1 of the pixel defining film PDL and the maximum width W2 of the bank BK may be parallel to a direction, and the direction may be perpendicular to the thickness direction DR3. Accordingly, the area of the bank BK may be smaller than the area of the pixel defining film PDL in a plan view. In a cross-sectional view parallel to the thickness direction DR3, the first to third sub light control parts SCP1, SCP2, and SCP3 may not overlap the non-light-emitting region NPXA, and at least a portion of each of the first to third light control parts CCP1, CCP2, and CCP3 may overlap the non-light-emitting region NPXA.

In a cross-sectional view parallel to the thickness direction DR3, a minimum width WT2 of each of the first to third sub light control parts SCP1, SCP2, and SCP3 may be smaller than a minimum width WT1 of each of the first to third light control parts CCP1, CCP2, and CCP3. Although FIG. 4 illustrates the minimum width WT2 of the first sub light control part SCP1 and the minimum width WT1 of the first light control part CCP1, the same description may be applied to the minimum width of each of the second sub light control part SCP2 and the third sub light control part SCP3 and the minimum width of each of the second light control part CCP2 and the third light control part CCP3.

In a cross-sectional view parallel to the thickness direction DR3, the minimum width WT2 of the first sub light control part SCP1 may be smaller than the minimum width WT1 of the first light control part CCP1. The minimum width WT2 of the first sub light control part SCP1 and the minimum width WT1 of the first light control part CCP1 may be parallel to a direction perpendicular to the thickness direction DR3. The minimum width WT2 of the first sub light control part SCP1 may be a width on a surface in contact with the inorganic encapsulation film TFM. The minimum width WT1 of the first light control part CCP1 may be a width on a surface in contact with the sub-inorganic film TFM-S. Since the first sub light control part SCP1 does not overlap the non-light-emitting region NPXA, and the first light control part CCP1 at least partially overlaps the non-light-emitting region NPXA, the minimum width WT2 of the first sub light control part SCP1 may be smaller than the minimum width WT1 of the first light control part CCP1.

In an embodiment, the inorganic encapsulation film TFM, the sub light control layer SCL, the light control layer CCL, and the like, which are disposed above the light-emitting element layer DP-ED, may be formed through a continuous process. Accordingly, the display device DD according to an embodiment may not include a filling layer between the light-emitting element layer DP-ED and the light control layer CCL.

The inorganic encapsulation film TFM may be formed by directly providing a material for forming the inorganic encapsulation film TFM onto the light-emitting element layer DP-ED. The sub light control layer SCL may be formed by directly providing a material for forming the sub light control layer SCL onto the inorganic encapsulation film TFM. The light control layer CCL may be formed by directly providing a material for forming the light control layer CCL onto the sub light control layer SCL. For example, each of the sub light control layer SCL and the light control layer CCL may be formed by an inkjet printing method or a photoresist method. However, this is only an example, and the method for forming the sub light control layer SCL and the light control layer CCL is not limited thereto.

The display device DD according to an embodiment may include the light-emitting element layer DP-ED, the inorganic encapsulation film TFM disposed above the light-emitting element layer DP-ED, and the sub light control layer SCL disposed above the inorganic encapsulation film TFM. The sub light control layer SCL may include first to third sub light control parts SCP1, SCP2, and SCP3 spaced apart from each other with the pixel defining film PDL therebetween. The first to third sub light control parts SCP1, SCP2, and SCP3 may include at least one quantum dot QD1_S and QD2_S, and may be disposed adj acent to the light-emitting element layer DP-ED that generates light, thereby improving light efficiency of the display device DD.

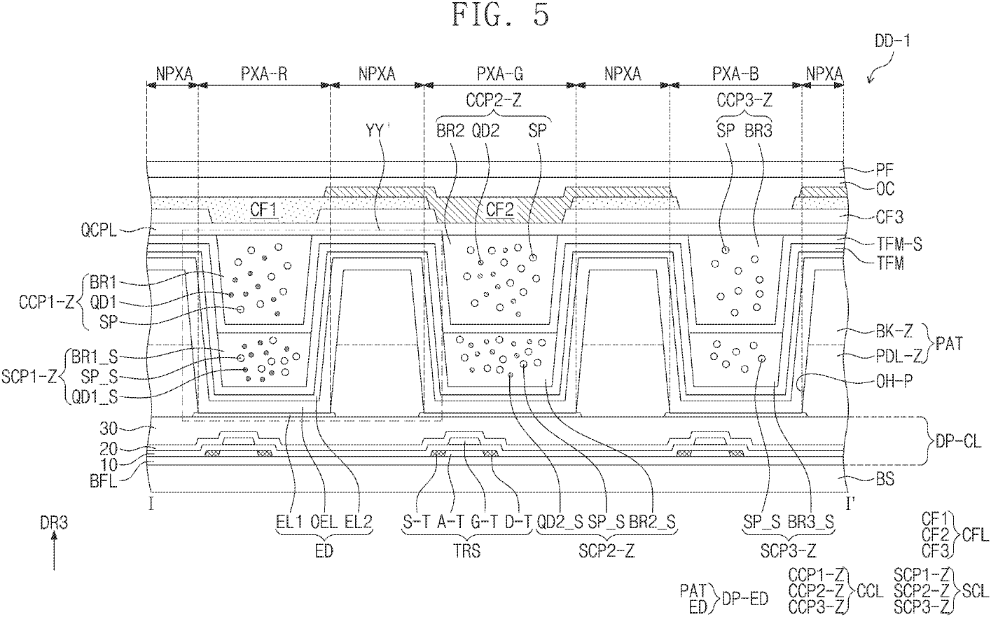

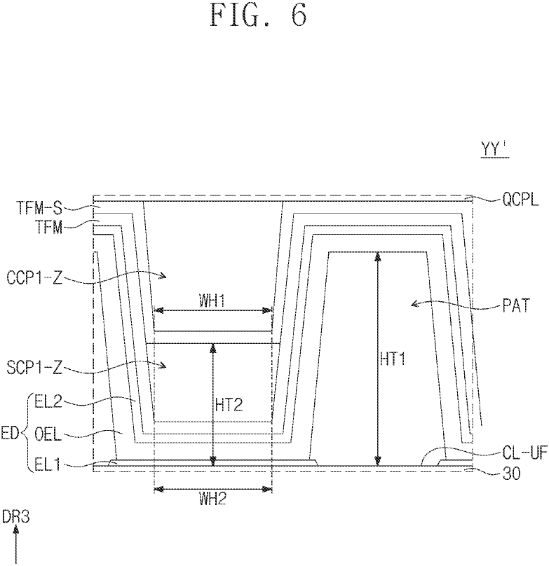

FIGS. 5, 7, and 8 are schematic cross-sectional views illustrating other embodiments of a display device according to the disclosure. FIG. 6 is an enlarged schematic cross-sectional view illustrating region YY′ of FIG. 5. Hereinafter, in the descriptions of FIGS. 5 to 8, contents duplicated with those described with reference to FIGS. 1 to 4 are not described again, and description will be focused on differences.

Compared to the display device DD described with reference to FIG. 3, a display device DD-1 illustrated in FIG. 5 may include a partition wall PAT. The pixel defining film PDL-Z and the bank BK-Z may be integrated to form the partition wall PAT. Therefore, in the process for manufacturing the display device DD-1, the forming of the pixel defining film PDL-Z and the forming of the bank BK-Z may be integrated into forming of the partition wall PAT, thereby improving manufacturing efficiency.

The partition wall PAT may be formed of an organic light blocking material or an inorganic light blocking material which contains a black pigment or a black dye. In another embodiment, the partition wall PAT may be formed of an optically transparent material. The partition wall PAT may overlap the non-light-emitting region NPXA. In the non-light-emitting region NPXA, the light-emitting layer OEL, the second electrode EL2, the inorganic encapsulation film TFM, the sub-inorganic film TFM-S, and the capping layer QCPL may be sequentially disposed above the partition wall PAT.

The partition wall PAT may have a partition wall opening OH-P defined therein. The first electrode EL1 of the light-emitting element ED may be exposed in the partition wall opening OH-P. First to third sub light control parts SCP1-Z, SCP2-Z, and SCP3-Z may be disposed in the partition wall opening OH-P. First to third light control parts CCP1-Z, CCP2-Z, and CCP3-Z may be disposed in the partition wall opening OH-P.

Referring to FIG. 5, the first to third sub light control parts SCP1-Z, SCP2-Z, and SCP3-Z may be spaced apart from each other with the partition wall PAT therebetween. The first to third light control parts CCP1-Z, CCP2-Z, and CCP3-Z may be spaced apart from each other with the partition wall PAT therebetween.

The first to third sub light control parts SCP1-Z, SCP2-Z, and SCP3-Z spaced apart from each other with the partition wall PAT therebetween may not overlap the non-light-emitting region NPXA. The first to third light control parts CCP1-Z, CCP2-Z, and CCP3-Z spaced apart from each other with the partition wall PAT therebetween may not overlap the non-light-emitting region NPXA. The first sub light control part SCP1-Z and the first light control part CCP1-Z may overlap the first light-emitting region PXA-R. The second sub light control part SCP2-Z and the second light control part CCP2-Z may overlap the second light-emitting region PXA-G. The third sub light control part SCP3-Z and the third light control part CCP3-Z may overlap the third light-emitting region PXA-B.

A sub-inorganic film TFM-S may be disposed between the first to third sub light control parts SCP1-Z, SCP2-Z, and SCP3-Z and the first to third light control parts CCP1-Z, CCP2-Z, and CCP3-Z, respectively. For example, the sub-inorganic film TFM-S may contact the first sub light control part SCP1-Z and the first light control part CCP1-Z in the first light-emitting region PXA-R. The sub-inorganic film TFM-S may contact the second sub light control part SCP2-Z and the second light control part CCP2-Z in the second light-emitting region PXA-G. The sub-inorganic film TFM-S may contact the third sub light control part SCP3-Z and the third light control part CCP3-Z in the third light-emitting region PXA-B.

In the non-light-emitting region NPXA, the sub-inorganic film TFM-S may be disposed between the partition wall PAT and the capping layer QCPL. For example, in the non-light-emitting region NPXA, the sub-inorganic film TFM-S may contact the inorganic encapsulation film TFM and the capping layer QCPL.

According to the disclosure, in a cross-sectional view parallel to the thickness direction DR3, a minimum width of each of the first to third sub light control parts SCP1-Z, SCP2-Z, and SCP3-Z may be substantially equal to a minimum width of each of the first to third light control parts CCP1-Z, CCP2-Z, and CCP3-Z. In this specification, the wording, “two widths are substantially equal” means that the difference between the two widths is about 10% or less, about 5% or less, or about 3% or less. For example, the minimum width of each of the first to third light control parts CCP1-Z, CCP2-Z, and CCP3-Z may be about 0.9 times, about 0.95 times, about 0.97 times, or about 1.0 times the minimum width of each of the first to third sub light control parts SCP1-Z, SCP2-Z, and SCP3-Z. In another embodiment, a difference between the minimum width of each of the first to third light control parts CCP1-Z, CCP2-Z, and CCP3-Z and the minimum width of each of the first to third sub light control parts SCP1-Z, SCP2-Z, and SCP3-Z may be within a tolerance range.

Referring to FIG. 6, the minimum width WH2 of the first sub light control part SCP1-Z may be same as the minimum width WH1 of the first light control part CCP1-Z (for example, about 1.0 times). Although FIG. 6 illustrates the minimum width WH2 of the first sub light control part SCP1-Z and the minimum width WH1 of the first light control part CCP1-Z, the same description may be applied to the minimum width of each of the second sub light control part SCP2-Z and the third sub light control part SCP3-Z and the minimum width of each of the second light control part CCP2-Z and the third light control part CCP3-Z.

Referring to FIG. 6, the partition wall PAT may have a first height HT1 parallel to the thickness direction DR3, and the first height HT1 may be a maximum height from a surface CL-UF of the circuit layer DP-CL (see FIG. 5) on which the first electrode EL1 is disposed. The first sub light control part SCP1-Z may have a second height HT2 parallel to the thickness direction DR3, and the second height HT2 may be a maximum height from a surface CL-UF of the circuit layer DP-CL (see FIG. 5) on which the first electrode EL1 is disposed. The surface CL-UF of the circuit layer DP-CL (FIG. 5) may be an upper surface of the third insulating layer 30.

The first height HT1 of the partition wall PAT may be greater than the second height HT2 of each of the first to third sub light control parts SCP1-Z, SCP2-Z, and SCP3-Z. Although FIG. 6 illustrates the first height HT1 of the partition wall PAT and the second height HT2 of the first sub light control part SCP1-Z, the same description may be applied to the second sub light control part SCP2-Z and third sub light control part SCP3-Z.

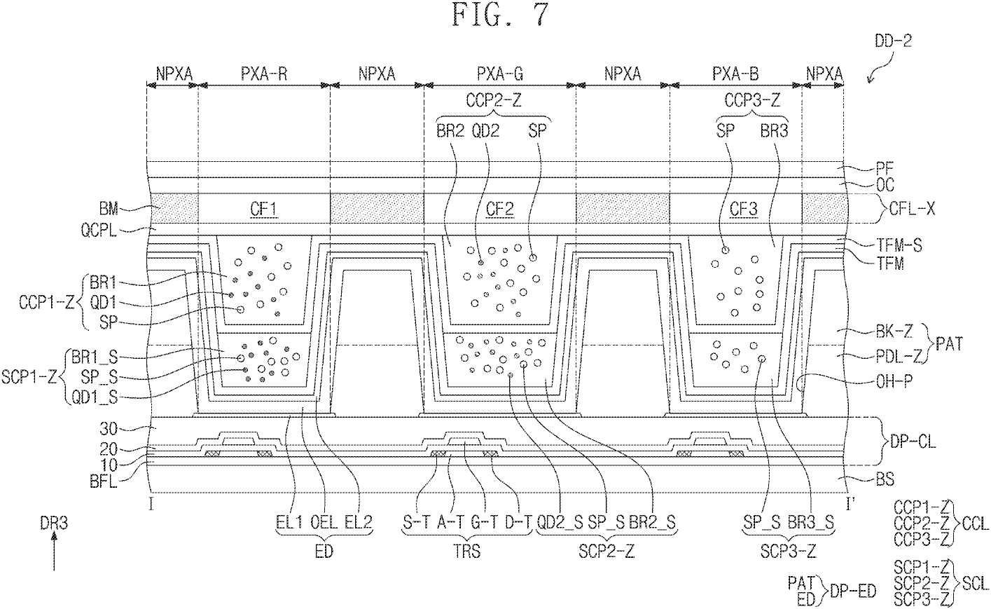

Compared to the display device DD-1 described with reference to FIG. 5, a display device DD-2 illustrated in FIG. 7 may further include a light blocking portion BM in a color filter layer CFL-X. In case that the color filter layer CFL-X includes the light blocking portion BM, the partition wall PAT may be formed of an optically transparent material.

The light blocking portion BM may be a black matrix. The light blocking portion BM may be formed of an organic light blocking material or an inorganic light blocking material which contains a black pigment or a black dye. The light blocking portion BM may prevent a light leakage phenomenon and may define boundaries between neighboring filters CF1, CF2 and CF3. The first to third filters CF1, CF2, and CF3 may be spaced apart from each other with the light blocking portion BM therebetween.

Compared to the display device DD-1 described with reference to FIG. 5, a display device DD-3 illustrated in FIG. 8 may include first to third light control units CCU1, CCU2, and CCU3. The display device DD-3 illustrated in FIG. 8 may not include the sub-inorganic film TFM-S.

The first to third sub light control parts SCP1-Z, SCP2-Z, and SCP3-Z and the first to third light control parts CCP1-Z, CCP2-Z, and CCP3-Z may be respectively integrated to form the first to third light control units CCU1, CCU2, and CCU3. For example, the first sub light control part SCP1-Z and the first light control part CCP1-Z may be integrated to form the first light control unit CCU1. The second sub light control part SCP2-Z and the second light control part CCP2-Z may be integrated to form the second light control unit CCU2. The third sub light control part SCP3-Z and the third light control part CCP3-Z may be integrated to form the third light control unit CCU3.

The first to third light control units CCU1, CCU2, and CCU3 may be spaced apart from each other with the partition wall PAT therebetween. The first to third light control units CCU1, CCU2, and CCU3 may not overlap the non-light-emitting region NPXA. The first to third light control units CCU1, CCU2, and CCU3 may be disposed between the inorganic encapsulation film TFM and the capping layer QCPL.

Hereinafter, a display device according to the disclosure will be described in detail with reference to Example (or Experimental Example) and Comparative Example. The following Examples are provided merely as examples to assist in the understanding of the disclosure, and the scope of the disclosure is not limited thereto.

Table 1 below shows the evaluation result of light efficiency and color gamut according to the thickness of a filling layer in display devices of Comparative Examples and Experimental Examples each including a filling layer. The display devices of Comparative Example 1 and Experimental Examples 1 to 3 have the same configuration except for the thickness of the filling layer. Each of the display devices of Comparative Example 1 and Experimental Examples 1 to 3 does not include a sub light control part and includes a filling layer disposed between an inorganic encapsulation film and a light control layer. The display device of Comparative Example 1 includes a filling layer having a thickness of about 4 µm, the display device of Experimental Example 1 includes a filling layer having a thickness of about 1 µm, the display device of Experimental Example 2 includes a filling layer having a thickness of about 2 µm, and the display device of Experimental Example 3 includes a filling layer having a thickness of about 3 µm.

In Table 1, light efficiency and color gamut are relative values in case that the value measured in the display device of Comparative Example 1 is 100%. The light efficiency may be obtained by evaluating the efficiencies for red light, green light, blue light, and white light. The color gamut may be evaluated based on BT2020 (standard of color gamut for display). The results in Table 1 are evaluated using CAS-140CT (Instrument Systems Corporation), SR-UL2 (TOPCON Corporation), and CM-2600D (KONICA MINOLTA Inc.).

TABLE 1

| Division | Red light (R, %) | Green light (G, %) | Blue light (B, %) | White light (W, %) | Color Gamut (Color Matching Ratio, %) |
|---|---|---|---|---|---|
| Experimental Example 1 | 106.2 | 106.7 | 109.5 | 107.0 | 92.6 |
| Experimental Example 2 | 104.2 | 104.5 | 106.0 | 104.6 | 92.5 |
| Experimental Example 3 | 102.1 | 102.3 | 102.8 | 102.3 | 92.3 |
| Comparative Example 1 | 100.0 | 100.0 | 100.0 | 100.0 | 92.2 |

Referring to Table 1, it may be understood that light efficiency and color gamut in Experimental Examples 1 to 3 are improved as compared to those in Comparative Example 1. It may be understood that, in Comparative Examples 1 and Experimental Examples 1 to 3, the efficiency of white light increases by about 2% or more in case that the thickness of a filler is decreased by about 1 µm. As the emission path of light generated in the light-emitting element layer decreases, it may be understood that the light efficiency is improved. Accordingly, it is considered that the display device according to an embodiment that does not include a filling layer and includes a sub light control part adjacent to the light-emitting layer would exhibit improved light efficiency.

Table 2 below shows evaluation results of light efficiency and color gamut in the display devices of Comparative Example 1 and Experimental Example 4. The display device of Comparative Example 1 in Table 2 is the same display device as described in Table 1, and the display device of Experimental Example 4 is a display device that does not include a filling layer between the inorganic encapsulation film and the light control layer. In Table 2, light efficiency and color gamut are relative values in case that the value measured in the display device of Comparative Example 1 is 100%. The light efficiency may be obtained by evaluating the efficiencies for red light, green light, blue light, and white light. The color gamut may be evaluated based on BT2020 (standard of color gamut for display). The results in Table 2 are evaluated using CAS-140CT (Instrument Systems Corporation), SR-UL2 (TOPCON Corporation), and CM-2600D (KONICA MINOLTA Inc.)

TABLE 2

| Division | Red light (R, %) | Green light (G, %) | Blue light (B, %) | White light (W, %) | Color Gamut (Color Matching Ratio, %) |
|---|---|---|---|---|---|
| Comparative Example 1 | 100.0 | 100.0 | 100.0 | 100.0 | 91.9 |
| Experimental Example 4 | 120.0 | 118.9 | 116.6 | 118.5 | 93.2 |

Referring to Table 2, it may be understood that the display device of Experimental Example 4 has improved light efficiency and color gamut as compared to the display device of Comparative Example 1. The display device of Experimental Example 4 does not include a filling layer. Accordingly, it is considered that the display device according to an embodiment that does not include a filling layer and includes a sub light control part adjacent to the light-emitting layer would exhibits improved light efficiency and color gamut.

The display device according to an embodiment may include a light-emitting element layer, an inorganic encapsulation film disposed above the light-emitting element layer, a sub light control layer disposed above the inorganic encapsulation film and containing quantum dots, a light control layer disposed above the sub light control layer and containing quantum dots, and a capping layer disposed above the light control layer. The sub light control layer may include first to third sub light control parts spaced apart from each other, and the light control layer may include first to third light control parts spaced apart from each other. The display device according to an embodiment may further include at least one of a sub-inorganic film and a partition wall. The sub-inorganic film may be disposed between the first to third sub light control parts and the first to third light control parts. A partition wall may be configured such that a pixel defining film of the light-emitting element layer and the bank of the light control layer are integrated. The display device according to an embodiment including the first to third sub light control parts disposed adjacent to a light-emitting layer of the light-emitting element layer may exhibit improved light efficiency and color gamut.

A display device according to an embodiment may include a sub light control part adjacent to a light-emitting layer that generates light, thereby exhibiting improved light efficiency and color gamut.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device comprising:
a circuit layer;
a light-emitting element layer disposed above the circuit layer;
an inorganic encapsulation film disposed above the light-emitting element layer;
a sub light control layer disposed above the inorganic encapsulation film and including a first sub light control part, a second sub light control part, and a third sub light control part, each spaced apart from each other in a direction perpendicular to a thickness direction;
a light control layer disposed above the sub light control layer and including a bank, first light control part, a second light control part, and a third light control part, the first to third light control parts spaced apart from each other in the direction;
a capping layer disposed above the light control layer and covering the light control layer; and
a color filter layer disposed above the capping layer and including a first filter, a second filter, and a third filter, wherein
the bank is disposed between the first light control part, the second light control part, and the third light control part,
the light-emitting element layer includes:
a pixel defining film with a pixel opening defined therein;
a first electrode exposed in the pixel opening;
a second electrode disposed above the first electrode; and
a light-emitting layer disposed between the first electrode and the second electrode, and
each of the sub light control layer and the light control layer includes quantum dots.

2. The display device of claim 1, wherein the pixel defining film is disposed between the first sub light control part, the second sub light control part, and the third sub light control part.

3. The display device of claim 1, wherein an upper surface of the bank contacts a lower surface of the capping layer in the thickness direction.

4. The display device of claim 1, further comprising:
a sub-inorganic film disposed directly between the sub light control layer and the light control layer.

5. The display device of claim 4, wherein
the pixel defining film is optically transparent, and
the bank comprises at least one of a black pigment and a black dye.

6. The display device of claim 4, wherein a minimum width of the pixel defining film in the direction is greater than a maximum width of the bank in the direction in a cross-sectional view.

7. The display device of claim 6, wherein a minimum width of each of the first to third sub light control parts in the direction is smaller than a minimum width of each of the first to third light control parts in the direction in a cross-sectional view.

8. The display device of claim 1, wherein
the pixel defining film and the bank are integrated to form a partition wall, and
the first to third sub light control parts and the first to third light control parts are each disposed in a partition wall opening defined in the partition wall.

9. The display device of claim 8, further comprising:
a sub-inorganic film disposed directly between the first to third sub light control parts and the first to third light control parts.

10. The display device of claim 8, wherein a minimum width of each of the first to third sub light control parts in the direction is substantially equal to a minimum width of each of the first to third light control parts in the direction in a cross-sectional view.

11. The display device of claim 8, wherein
a first height of the partition wall is greater than a second height of each of the first to third sub light control parts in a cross-sectional view, and
each of the first height and the second height is defined as a maximum height in the thickness direction from a surface of the circuit layer.

12. The display device of claim 8, wherein
the partition wall is optically transparent, and
the color filter layer further includes a light blocking portion overlapping the partition wall in the thickness direction.

13. The display device of claim 8, wherein
the first light control part and the first sub light control part are integrated to form a first light control unit,
the second light control part and the second sub light control part are integrated to form a second light control unit,
the third light control part and the third sub light control part are integrated to form a third light control unit,
the first to third light control units are spaced apart from each other, and
the partition wall is disposed between the first light control unit, the second light control unit, and the third light control unit.

14. The display device of claim 1, wherein each of the sub light control layer and the light control layer further includes a scatterer.

15. A display device comprising:
a light-emitting region and a non-light-emitting region;
a light-emitting element layer;
an inorganic encapsulation film disposed above the light-emitting element layer;
a sub light control layer disposed above the inorganic encapsulation film and including a first sub light control part, a second sub light control part, and a third sub light control part, each spaced apart from each other in a direction perpendicular to a thickness direction;
a light control layer disposed above the sub light control layer and including a bank, a first light control part, a second light control part, and a third light control part, the first to third light control parts spaced apart from each other in the direction;
a sub-inorganic film disposed between the sub light control layer and the light control layer;
a capping layer disposed above the light control layer and covering the light control layer; and
a color filter layer disposed above the capping layer and including a first filter, a second filter, and a third filter, wherein
the bank is disposed between the first light control part, the second light control part, and the third light control part,
each of the sub light control layer and the light control layer includes quantum dots,
at least a portion of each of the first to third light control parts overlaps the non-light-emitting region in the thickness direction, and
the first to third sub light control parts do not overlap the non-light-emitting region in the thickness direction.

16. The display device of claim 15, wherein
the sub-inorganic film is disposed between the sub light control layer and the light control layer in the light-emitting region, and
the sub-inorganic film is disposed between the inorganic encapsulation film and the light control layer in the non-light-emitting region.

17. The display device of claim 15, wherein
the light-emitting element layer comprises:
a pixel defining film with a pixel opening defined therein;
a first electrode exposed in the pixel opening;
a second electrode disposed above the first electrode; and
a light-emitting layer disposed between the first electrode and the second electrode, and
a minimum width of the pixel defining film in the direction is greater than a maximum width of the bank in the direction in a cross-sectional view.

18. A display device comprising:
a light-emitting region and a non-light-emitting region;
a light-emitting element layer;
an inorganic encapsulation film disposed above the light-emitting element layer;
a sub light control layer disposed above the inorganic encapsulation film and including a first sub light control part, a second sub light control part, and a third sub light control part, each spaced apart from each other in a direction perpendicular to a thickness direction;
a light control layer disposed above the sub light control layer and including a first light control part, a second light control part, and a third light control part, each spaced apart from each other in the direction;
a sub-inorganic film disposed between the sub light control layer and the light control layer;
a capping layer disposed above the light control layer and covering the light control layer;
a color filter layer disposed above the capping layer and including a first filter, a second filter, and a third filter; and
a partition wall, wherein
the light-emitting element layer includes:
a first electrode;
a second electrode disposed above the first electrode; and
a light-emitting layer disposed between the first electrode and the second electrode,
each of the sub light control layer and the light control layer includes quantum dots,
the partition wall is disposed between the first sub light control part, the second sub light control part, and the third sub light control part, and
the partition wall is disposed between the first light control part, the second light control part, and the third light control part.

19. The display device of claim 18, wherein
the sub-inorganic film is disposed between the first to third sub light control parts and the first to third light control parts in the light-emitting region, and
the sub-inorganic film is disposed between the partition wall and the capping layer in the non-light-emitting region.

20. The display device of claim 18, wherein the first to third sub light control parts and the first to third light control parts do not overlap the non-light-emitting region in the thickness direction.
